(19) United States
(12) Patent Application Publication
(10) Pub. No.: US 2011/0192462 A1
(43) Pub. Date: Aug. 11, 2011

(54) SOLAR CELLS

(75) Inventors: Claudio Truzzi, Incourt (BE); Steve Lerner, Carlisle, MA (US)

(73) Assignee: Alchimer, S.A.

(21) Appl. No.: 12/983,094

(22) Filed: Dec. 31, 2010

Related U.S. Application Data
(60) Provisional application No. 61/291,911, filed on Jan. 3, 2010.

(51) Int. Cl. H01L 31/02; H01L 31/0264; H01L 31/18

(52) U.S. Cl. 136/261; 136/252; 438/98; 257/E31.124

(57) ABSTRACT

A solar cell is provided herein. The solar cell includes a substantially transparent substrate, a substantially thin and transparent nickel-based conformal layer deposited on the substrate surface, and at least one interconnect formed on the conformal layer to facilitate energy conversion of the solar cell. The conformal layer can be made from a nickel-based material and is designed to enhance ohmic contact to the interconnect. The conformal layer can also act to facilitate the conversion of light energy into electrical current by the interconnect, while minimizing energy loss, such that the overall conversion efficiency of the solar cell can be improved. The conformal layer can further facilitate transmission of electrical current along the solar cell. A method for manufacturing a solar cell is also provided.

### RELATED APPLICATIONS

This application claims priority to U.S. Provisional Patent Application Ser. No. 61/291,911, filed Jan. 3, 2010, the content of which is incorporated herein by reference in its entirety.

### FIELD OF THE INVENTION

The present invention relates to solar cells and methods for fabricating same.

### BACKGROUND

Solar cells may be used for powering a number of objects, including the likes of calculators and satellites. In some instances, solar cells may also be referred to as solar cells or modules (group or array of cells electrically connected and packaged in one frame). Solar cells are capable of converting sunlight into electricity for use in a variety of applications.

Solar cells may be made of semiconductor materials, such as silicon. Functionally, when light strikes a solar cell, certain portions of the light may be absorbed within the semiconductor material. This means that energy of the absorbed light may be transferred to the semiconductor material. This energy is capable of knocking loose electrons within the semiconductor material allowing them to flow freely. The free flowing electrons can act to generate current. Using electric fields within the solar cell and metal contacts on the top and bottom of the solar cell, current may be drawn off to be used externally. The current, together with the voltage of the solar cell, which may be a result of its built-in electric fields, define the power (or wattage) that a solar cell can produce.

### SUMMARY OF THE INVENTION

The present invention provides, in one embodiment, a solar cell having a substrate that can permit external radiation to pass therethrough. The substrate, in an embodiment, can be made from a transparent material, such as glass, quartz, sapphire or other materials transparent to external radiation. The solar cell can also include a layer of a functional layer formed over the substrate to facilitate conversion of the external radiation into electrical current and to provide an electrical connection along the solar cell. The functional layer, in an embodiment, can include a semiconductor layer, such as that made from light-absorbing silicon material. The layer of interconnect can also include a metal layer for use as an electrode for the solar cell. The solar cell can further include a substantially conformal layer deposited between the substrate and the functional layer. In one embodiment, the conformal layer can be made from a material having low resistivity to electrical current so as to minimize disruption, while improving overall transmission of electrical current from the functional layer along the conformal layer, such that more of the electrical current can be available for use. In a preferred embodiment, the conformal layer is made from nickel-boron.

The present invention also provides, in another embodiment, a method for manufacturing a solar cell. The method includes initially providing a substrate that can permit external radiation to pass therethrough. Next, a substantially thin conformal layer can be placed on the substrate. The conformal layer, in one embodiment, can be made from a material having relatively low resistivity to electrical current and that can minimize disruption while improving overall transmission of electrical current along the solar cell. In placing the conformal layer on to the substrate, a pattern for the conformal layer can be defined. Thereafter, a functional layer can be deposited on to the conformal layer. The functional layer, in an embodiment, can be designed to facilitate conversion of external radiation into electrical energy and to provide an electrical connection to the conformal layer. The functional layer can include a semiconductor layer, such as that made from light-absorbing silicon material. The layer of interconnect can also include a metal layer for use as an electrode for the solar cell. In depositing the layer of interconnect on to the conformal layer, a pattern for the layer of interconnect can be defined.

In another embodiment of the present invention, a method for converting light radiation to electrical energy is provided. The method includes initially providing a functional layer made from a material that can facilitate conversion of light radiation into electrical current and that can provide an electrical connection. The functional layer, in an embodiment, can include a semiconductor layer, such as that made from light-absorbing silicon material for conversion of light into electrical current. The functional layer can also include a metal layer for use as an electrode for the solar cell. Next, a substantially thin conformal layer can be placed against a surface of the functional layer. In an embodiment, the conformal layer may be made from a material having relatively low resistivity to electrical current and that can minimize disruption while improving overall transmission of electrical current from the functional layer along the conformal layer. Specifically, the conformal layer can be made from a metal-based material, such as nickel-boron. Thereafter, light radiation can be directed through the conformal layer to the functional layer, where the light radiation can be converted into electrical current for subsequent use. It should be appreciated that the electrical current converted from light radiation can be permitted to flow from the metal layer of the functional layer into and along the conformal layer with minimal energy loss, such that more of the electrical current can be available for use.

### BRIEF DESCRIPTION OF THE DRAWINGS

FIG. 1 illustrates a view of a solar cell in accordance with one embodiment of the present invention.

FIG. 2A-2J illustrate a process flow for producing the solar cell of FIG. 1 in accordance to one embodiment of the present invention.

### DETAILED DESCRIPTION

### Solar Cell

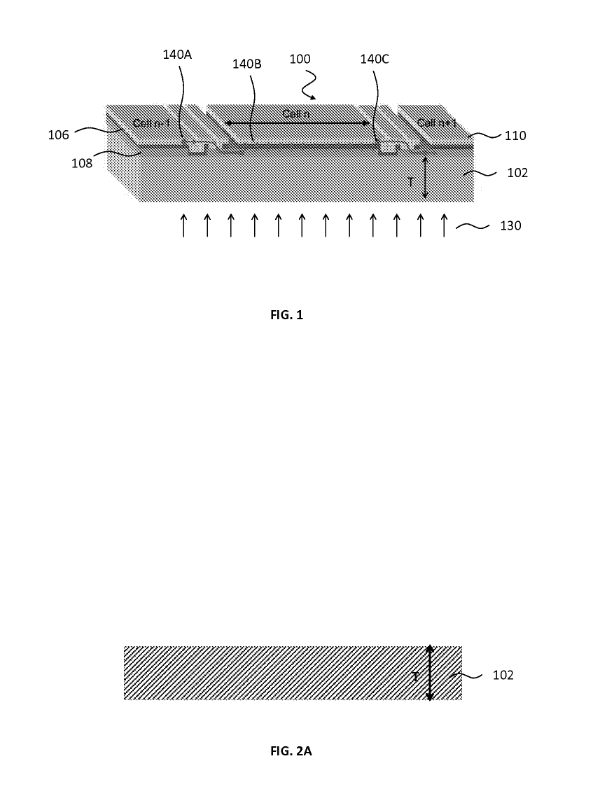

Reference is now made to FIG. 1 illustrating a perspective view of a solar cell 100 according to one embodiment of the present disclosure. The solar cell 100 includes a substrate 102 designed to serve as a base or supporting material to which additional layers or materials may be applied, formed or deposited thereon. Substrate 102, in an embodiment, can be made from a material which permits solar radiation or light to pass therethrough. For example, substrate 102 can be made from glass, quartz, sapphire, or similar materials. Substrate 102, in an embodiment, can also be provided with substantially uniform thickness to provide a substantially uniform distance across which the solar radiation needs to travel before reaching the underlying layers of the solar cell 100.

Solar cell 100 may further include a substantially conformal layer 108 deposited over the substrate 102. In an embodiment, conformal layer 108 of the present invention may be minimally resistive and relatively conductive. Specifically, the conformal layer 108 may be more electrically conductive and less resistive than, for instance, transparent conductive oxide (TCO), such as Indium Tin Oxide (ITO), or similar materials currently available commercially. In some embodiments, the conformal layer 108 of the present invention has a resistivity of about 30% lower, about 40% lower, or about 50% lower than that of TCO.

As used herein, conformal layer means a layer that is capable of being deposited in a substantially uniform manner throughout an exterior perimeter of the underlying layer, while maintaining a substantially uniform thickness throughout. For example, a conformal layer 108 deposited over an underlying material (e.g., substrate 102) may have substantially similar film thickness at a top surface, a bottom surface, and sidewalls of the underlying material. In one embodiment, conformal layer 108 may be able to maintain substantially uniform film thickness throughout the perimeter of the underlying layer, such as substrate 102, regardless of any features (e.g., linewidths, vias, interconnects) that may be present on the surface of the underlying layer(s). In other words, regardless of the interconnect features, conformal layer 108 may still be able to provide substantially uniform thickness across the surface of substrate 102.

The conformal layer 108, in one embodiment, may be designed to allow light, solar radiation, or other similar external radiations passing through substrate 102 to reach the underlying layers or components of solar cell 100. For example, conformal layer 108 may be substantially transparent or thin to permit solar radiation to reach an active light-absorbing material (e.g., thin-film silicon layer 106, metal contacts 110) deposited on the conformal layer. The conformal layer 108 can also serve as an ohmic contact to transport photogenerated charge carriers away from the light-absorbing material across the solar cell 100. To that end, the conformal layer 108 may have substantially low contact resistance with the underlying light-absorbing material.

To minimize energy loss and enhance overall conversion efficiency by the solar cell 100 of the present invention, conformal layer 108 may be made, in an embodiment, from a material that is electrically conductive, while having a low resistivity. In one embodiment, such a material can be a metal-based material, and can include a nickel-based material, a cobalt-based material, their alloys, and/or combinations thereof. In some embodiments, the conformal layer 108 may be made from a titanium-based material, tantalum-based material, nitride-based material, silicon-nitride based material, titanium-nitride based material, tantalum-nitride based material, titanium-tantalum based material, or alloys thereof, among others. In a preferred embodiment, the conformal layer 108 may be made from nickel-boron (NiB). In particular, the utilization a substantially thin and transparent nickel-boron conformal layer 108 can, in embodiment, minimize resistance to the flow of electrical current, converted from external radiation, through solar cell 100 with minimal disruption (and in some instances, no disruption) to the flow of such electrical current along the solar cell 100. In that way, with relatively less loss of current or energy flowing through the conformal layer 108, it follows that there is a relatively higher percentage of the overall amount of electrical current that is available for use. In some aspects, the improvement in conversion efficiency may be at least about 1%, at least about 2%, at least about 5%, or at least about 10%, or at least about 15%, or at least about 20%, or at least about 25%, or at least about 30%, or at least about 35%, or at least about 40%.

In one aspect of the present invention, the nickel-boron conformal layer 108 may be deposited using suitable electroless metal deposition methods known in the art. In another aspect, an activation step may precede the deposition step, and can involve immersing the silicon substrate having an oxide layer thereon within an activation solution, followed by plating the treated substrate with suitable electroless metal plating techniques known in the art.

As used herein, external radiation includes, for instance, alpha radiation, beta radiation, gamma radiation and solar energy, among others. In some instances, the external radiation may be natural occurring or artificially generated source (e.g., light from a powered source). In order to permit external radiation to pass therethrough, the conformal layer 108 may be substantially transparent. In one embodiment, the conformal layer 108 may be sufficiently thin and transparent to permit the external radiation to penetrate through the thickness of the conformal layer 108 to the underlying components of the solar cell 100.

Solar cell 100, as illustrated in FIG. 1, may also include a substantially thin semiconductor layer, such as a thin-film light-absorbing silicon layer 106, deposited on the conformal layer 108. In certain embodiments, silicon layer 106 may include multiple layers such as a n+ diffuse layer and/or a p-n junction layer. The silicon layer 106, in an embodiment, can act to bring about an energy conversion process. In particular, the light energy entering the silicon layer 106 may loosen (i.e., knock lose) electrons within the silicon layer 106, causing the electrons within the silicon layer 106 to become free flowing, resulting in the generation of current. Silicon layer 106 may also facilitate the formation of an array of active and/or passive elements over or about the conformal layer 108. The array of active and/or passive elements may be collectively referred to as “interconnects,” and can include patterned electrical integrated circuits, such as metal contacts 110.

As shown in FIG. 1, solar cell 100 can further include metal contacts 110 positioned on the light absorbing silicon layer 106, and, in certain instances, about a portion of the solar cell 100. In an embodiment, the metal contacts 110 can be configured to define patterns and/or layouts in accordance with a desired circuit layout and/or electrical design. The metal contacts 110 may function as electrodes of the solar cell 100 and can act to facilitate the flow of electrons across solar cell 100. In particular, the metal contacts 110 can act to provide an electrical connection to the conformal layer 108 along which the electrons (i.e., electrical current) may move.

The light-absorbing silicon layer 106 and the metal contacts 110, may be referred to as a “functional layer.” Together, these layers may facilitate current generation across the solar cell 100. As such, directly and/or indirectly, these layers may be responsible for determining the conversion efficiency of a solar cell 100. In an embodiment, these layers together may be capable of performing at least one complete electronic circuit function (e.g., execute a command).

As used herein, conversion efficiency is a measure of the effectiveness of the energy conversion by describing the ratio between the energy supplied and the energy input. For example, a solar cell having a conversion efficiency of about 35% means that about 35% of the incoming solar energy can be converted into electrical energy, with the interconnects being one of the primary drivers in the conversion process. The energy being converted may be used by electrical and/or mechanical devices in real-time (e.g., instantaneously), be stored for future use (e.g., battery), or be incorporated in a hybrid system where portions of the converted energy may be used while the remaining portions may be stored.

As used herein, standard test condition means testing a solar cell at about 1000 W/m² (watts per square meter) of light input with the solar cell being at a temperature of about 25° C. and an air mass of about 1.5. The standard test condition may also be applied to solar modules, solar cells, photovoltaic modules, among other devices and apparatuses.

In an example, when sunlight 130 or other external radiation strikes substrate 102, substrate 102, made from glass, quartz, sapphire or substantially similar transparent materials, can allow the sunlight 130 to pass through to the conformal layer 108. In some instances, the sunlight 130 may subsequently pass through the thin transparent conformal layer 108 to reach the semiconductor layer, i.e., the thin-film silicon layer 106. The sunlight 130 that reaches the silicon layer 106 may bring about an energy conversion process within the silicon layer 106. In particular, the light energy may be able to loosen (i.e., knock lose) electrons within the silicon layer 106, causing the electrons within the silicon layer 106 to become free flowing, resulting in the generation of current along the solar cell 100. As illustrated in FIG. 1, the design of the solar cell 100 of the present invention allows the free flowing electrons to flow from point 140A of metal layer 110 in cell n−1, through the conformal layer 108, and into the various points 140B of adjacent cell n. Likewise, the current flow may be repeated with electrons flowing from point 140C of metal layer 110 in cell n, through another portion of the conformal layer 108, and into various areas of adjacent cell n+1. Moreover, since the conformal layer 108 is made from a material, such as nickel-boron, that can minimize resistance to current flow from the metal layer 110 with minimal disruption to such current flow through the conformal layer 108, there can result relatively less loss of current or energy flowing along the solar cell 100. As such, there can be a relatively higher percentage of the overall amount of electrical current or energy that is available for use.

In some embodiments, a covering layer (not shown) may be selectively formed over the metal contacts 110. Should it be desired, the covering layer may also be deposited over side wall of the solar cell 100, so as to cover the sidewalls of the substrate 102, the conformal layer 108, the thin-film silicon 106 and the metal contacts 110. The covering layer, in one embodiment, may assist to enhance the energy conversion process. In particular, the covering layer can assist in directing more external radiation, such as sunlight, to the underlying layers, including the interconnects for the energy conversion process. In some instances, the covering layer may be an anti-reflective layer so as to minimize the amount of radiation that may be reflected away from solar cell 100. In other instances, the covering layer may also be a protective layer. The protective/covering layer used in connection with the solar cell 100 of the present invention, in one embodiment, can be made from a material including silicon dioxide, silicon nitride, among others.

With the presence of the various layers on substrate 102, it should be appreciated that in some embodiments the substrate 102 may need to be substantially thin (e.g., minimize thickness (T) of the substrate 102) to minimize diffraction of incoming light.

Methods, processes and techniques of fabricating solar cells having the features, functionalities and attributes described above are discussed below.

### Fabrication of Solar Cell

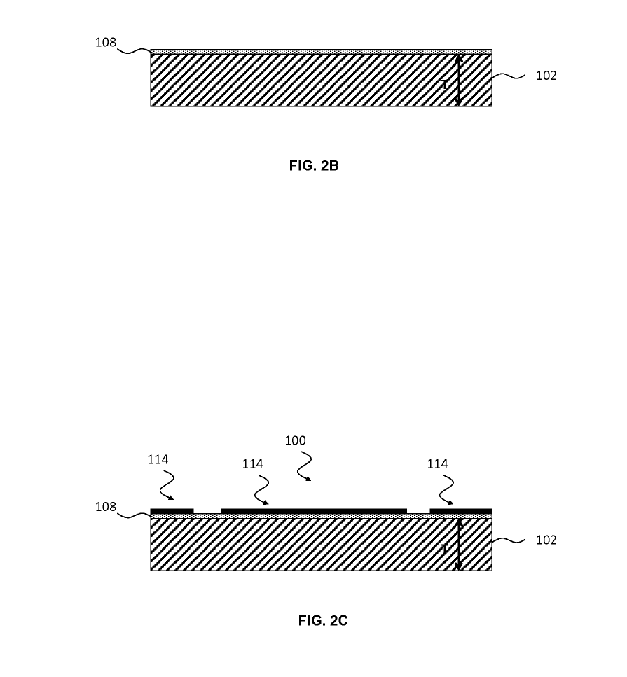

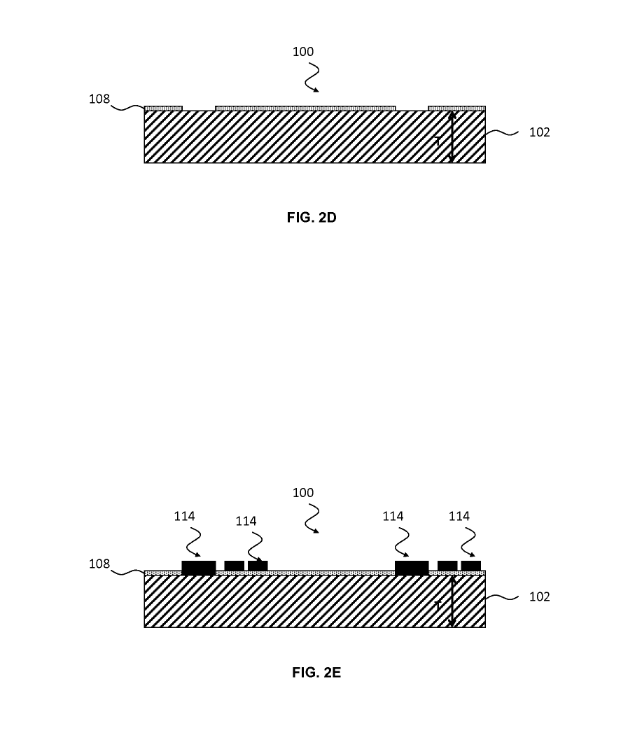

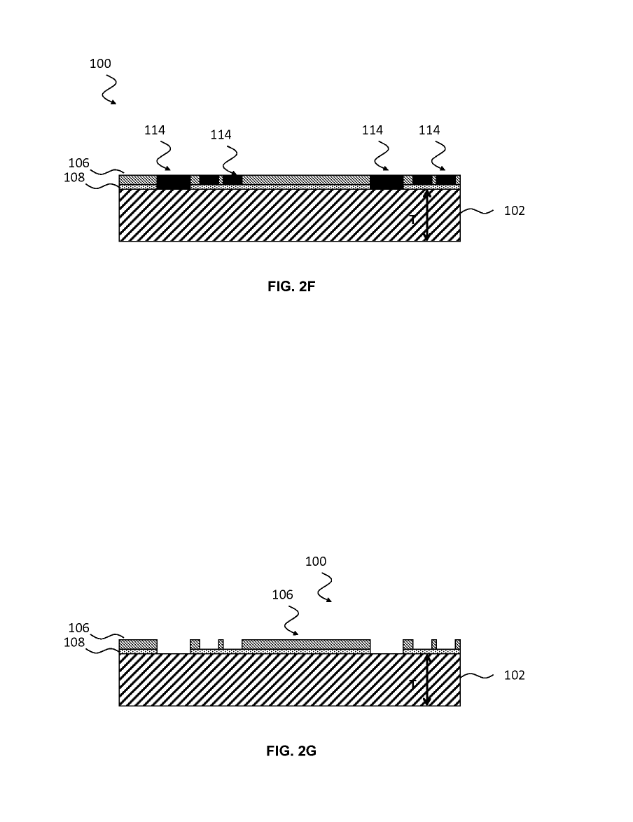

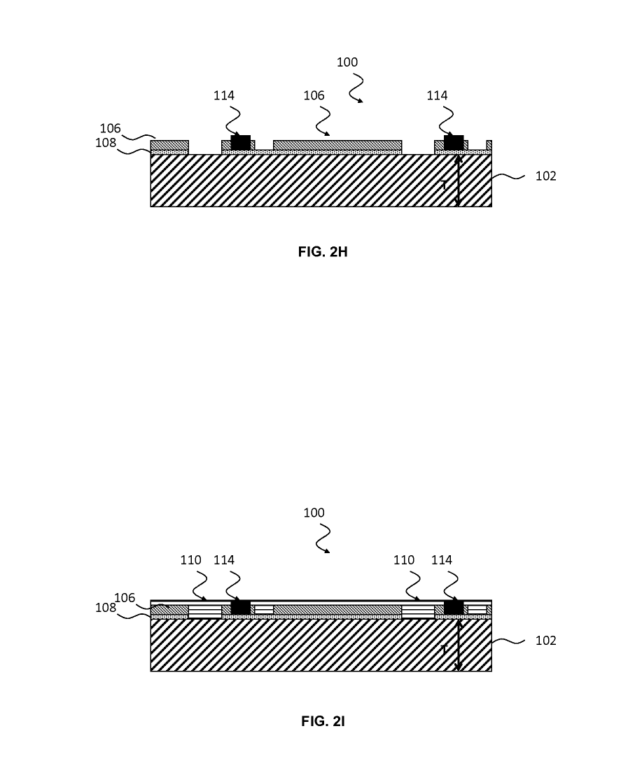

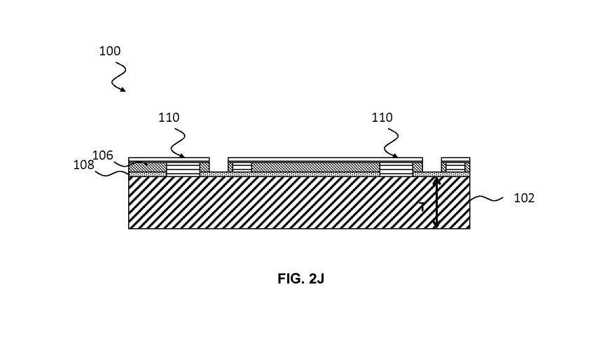

Reference is now made to FIGS. 2A-2J, which illustrate a process flow for fabricating the solar cell 100 of FIG. 1, according to one embodiment of the present disclosure.

FIG. 2A shows a substrate 102 for use in the construction of the solar cell 100 of the present invention. In one embodiment, substrate 102 may be made from glass, quartz or sapphire. In the alternative, the substrate 102 may be any suitable material that can be substantially transparent and may be able to serve as a base material for which subsequent processing steps may be carried out.

In some embodiments, the thickness (T) of the substrate 102 may be up to about 700 microns, or up to about 600 microns, or up to about 500 microns, or up to about 400 microns, or up to about 300 microns, or up to about 200 microns, or up to about 100 microns, or up to about 50 microns. In some aspects of the present disclosure, the thickness (T) of the substrate 102 may be in the range of from about 500 microns to about 700 microns, or from about 100 microns to about 700 microns, or from about 100 microns to about 500 microns, or from about 100 microns to about 300 microns, or from about 10 microns to about 300 microns, or from about 10 microns to about 200 microns, or from about 10 microns to about 100 microns, or from about 10 microns to about 50 microns, or from about 40 microns to about 350 microns, or from about 40 microns to about 250 microns, or from about 40 microns to about 200 microns, or from about 40 microns to about 150 microns, or from about 40 microns to about 100 microns, or from about 40 microns to about 50 microns. Of course, the substrate 102 can be provided with different varying thicknesses as desired.

FIG. 2B shows a conformal layer 108 being deposited over the substrate 102 utilizing methods known in the art. In one embodiment, the conformal layer 108 may have a thickness of up to about 100 nm. In some embodiments, the conformal layer 108 may have a thickness of up to about 90 nm, or up to about 80 nm, or up to about 70 nm, or up to about 60 nm, or up to about 50 nm, or up to about 40 nm, or up to about 30 nm, or up to about 20 nm, or up to about 10 nm, or up to about 5 nm. In other embodiments, the conformal layer 108 may have a thickness of at least about 5 nm, or at least about 10 nm, or at least about 15 nm, or at least about 25 nm, or at least about 35 nm, or at least about 45 nm, or at least about 55 nm, or at least about 65 nm, or at least about 75 nm, or at least about 85 nm, or at least about 95 nm. In some aspects of the present disclosure, the conformal layer 108 may have thicknesses in the range of from about 5 nm to about 100 nm, or from about 5 nm to about 50 nm, or from about 5 nm to about 25 nm, or from about 5 nm to about 20 nm, or from about 5 nm to about 10 nm, or from about 10 nm to about 90 nm, or from about 10 nm to about 50 nm, or from about 10 nm to about 25 nm, or from about 10 nm to about 20 nm.

In some embodiments, the conformal layer 108 may be up to 99% transparent, or up to 95% transparent, or up to 90% transparent, or up to 80% transparent, or up to 70% transparent, or up to 60% transparent, or up to 50% transparent. In other embodiments, the conformal layer 108 may be at least about 55% transparent, or at least about 65% transparent, or at least about 75% transparent, or at least about 85% transparent, or at least about 98% transparent. In some instances, the transparency of the conformal layer 108 may be in the range of from about 50% to about 99%, or from about 50% to about 95%, or from about 50% to about 90%, or from about 50% to about 80%, or from about 60% to about 99%, or from about 60% to about 95%, or from about 60% to about 90%, or from about 60% to about 80%, or from about 70% to about 99%, or from about 70% to about 95%, or from about 70% to about 90%, or from about 70% to about 80%, or from about 80% to about 99%, or from about 80% to about 95%, or from about 80% to about 90%.

As noted above, to enhance conversion efficiency of the solar cell 100 of the present invention, the conformal layer 108 may be made from a nickel-based material, a cobalt-based material, their alloys, and/or combinations thereof. In some embodiments, the conformal layer 108 may be made from a titanium-based material, tantalum-based material, nitride-based material, silicon-nitride based material, titanium-nitride based material, tantalum-nitride based material, titanium-tantalum based material, or alloys thereof, among others.

In one embodiment, the nickel-boron alloy, as a conformal layer 108, may be deposited over the substrate 102 by suitable electroless metal deposition techniques, such as those known in the art. The presence of the nickel-boron alloy layer may help to minimize (and in some instances, prevent) metals from leaching into the interconnects. In other words, the nickel-boron alloy may be capable of functioning as a barrier layer by minimizing or preventing the migration or diffusion of copper or other conductive material from penetrating through to the substrate 102. The nickel-boron conformal layer 108 can also act to lessen contact resistance with the underlying interconnects.

In some embodiments, the conformal layer may be deposited in wet conditions compatible with industrial constraints. The deposition process utilized in connection with the present invention enables coating of substantially uniform thickness across the surface of the substrate. In one embodiment, a method of preparing the substrate for nickel-based material deposition as the conformal layer 108 includes:
a) Bringing a semiconductor substrate into contact with a liquid solution comprising:
   (1) a protic solvent;
   (2) at least one diazonium salt;
   (3) At least one monomer that is chain-polymerizable and soluble in the protic solvent;
   (4) at least one acid in a sufficient quantity to stabilize the diazonium salt by adjusting the pH of the solution to a value less than 7, preferably less than 2.5; and
b) polarizing the surface according to a potentio- or galvano-pulsed mode for a duration sufficient to form a film having a thickness of at least 80 nanometers, and in some instances between 100 and 500 nanometers.

The protic solvent used in the aforementioned method may be chosen from the group consisting of water (e.g., deionized or distilled water); hydroxylated solvents (e.g., alcohols having 1 to 4 carbon atoms); carboxylic acids having 2 to 4 carbon atoms (e.g., formic acid, acetic acid, and mixtures thereof).

Thus, according to a particular characteristic, the diazonium salt may be an aryldiazonium salt chosen from the compounds of the following formula (I):

R—N₂⁺,A⁻ (I)

in which:
(1) A represents a monovalent anion,
(2) R represents an aryl group.

Examples of an aryl group R include unsubstituted, mono- or polysubstituted aromatic or heteroaromatic carbon structures, consisting of one or more aromatic or heteroaromatic rings, each comprising 3 to 8 atoms, the heteroatom(s) being chosen from N, O, S, or P; and optional substituent(s) including electron-attracting groups such as nitrite, aldehyde, ketones, nitrile, carboxyl, amino, esters and the halogens.

Examples of R groups include nitrophenyl and phenyl groups.

Among the compounds of formula (I) above, A may be chosen from inorganic anions such as halides like I⁻, Br⁻ and Cl⁻, haloboranes such as tetrafluoroborane, and organic anions such as alcoholates, carboxylates, perchlorates and sulphates.

In some embodiments, the diazonium salt of the aforementioned formula (I) may be chosen from phenyldiazonium tetrafluoroborate, 4-nitrophenyldiazonium tetrafluoroborate, 4 bromophenyldiazonium tetrafluoroborate, 2-methyl-4-chlorophenyldiazonium chloride, 4-benzoylbenzenediazonium tetrafluoroborate, 4 cyano-phenyldiazonium tetrafluoroborate, 4-carboxyphenyldiazonium tetrafluoroborate, 4-acetamidophenyldiazonium tetrafluoroborate, 4-phenylacetic acid diazonium tetrafluoroborate, 2-methyl-4-[(2-methylphenyl)-diazenyl]benzenediazonium sulphate, 9,10-dioxo-9,10-dihydro-1-anthracenediazonium chloride, 4-nitrophthalenediazonium tetrafluoroborate, and napthalenediazonium tetrafluoroborate, 4-amino-phenyldiazonium chloride.

In some instances, the diazonium salt may be chosen from phenyldiazonium tetrafluoroborate and 4-nitrophenyldiazonium tetrafluoroborate.

The diazonium salt may be generally present within the liquid electrografting solution in a quantity between 10⁻³ and 10⁻¹M, or between 5×10⁻³M and 3×10⁻²M.

Generally speaking, an electrografting solution contains at least one monomer that is chain-polymerizable and soluble in the protic solvent.

“Soluble in a protic solvent” is here understood to denote any monomer or mix of monomers whose solubility in the protic solvent is at least 0.5M.

In some embodiments, the monomers may be chosen from vinyl monomers soluble in the protic solvent and satisfying the following general formula (II):

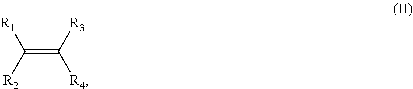

in which identical or different groups R1 to R4 represent a monovalent non-metal atom such as a halogen atom or a hydrogen atom, or a saturated or unsaturated chemical group such as a C1-C6 alkyl or aryl, a —COOR5 group in which R5 represents a hydrogen atom or a C1-C6 alkyl, nitrile, carbonyl, amine or amide group.

In some instances, water-soluble monomers may be used. Such monomers may be chosen from ethylenic monomers comprising pyridine groups such as 4-vinylpyridine or 2-vinylpyridine, or from ethylenic monomers comprising carboxylic groups such as acrylic acid, methacrylic acid, itaconic acid, maleic acid, fumaric acid and their sodium, potassium, ammonium or amine salts, amides of these carboxylic acids and in particular acrylamide and methacrylamide along with their N-substituted derivatives, their esters such as 2-hydroxyethyl methacrylate, glycidyl methacrylate, dimethylamino- or diethylamino (ethyl or propyl) (meth)acrylate and their salts, quaternized derivatives of these cationic esters such as, for example, acryloxyethyl trimethylammonium chloride, 2-acrylamido-2-methylpropane sulphonic acid (AMPS), vinylsulphonic acid, vinylphosphoric acid, vinyllactic acid and their salts, acrylonitrile, N-vinylpyrrolidone, vinyl acetate, N-vinylimidazoline and its derivatives, N vinylimidazole and derivatives of the diallylammonium type such as dimethyldiallylammonium chloride, dimethyldiallylammonium bromide and diethyldiallylammonium chloride.

The quantitative composition of the liquid electrografting solution may vary within broad limits.

Generally speaking, this solution may include:
(a) at least 0.3M of polymerizable monomer(s),
(b) at least 5×10⁻³ M of diazonium salt(s), the molar ratio of the polymerizable monomer(s) to the diazonium salt(s) being between 10 and 300.

As previously mentioned, the use of an electrografting protocol in pulsed mode constitutes another aspect of the present disclosure, to the extent that this particular protocol makes it possible, completely unexpectedly and in contrast to a cyclic voltammetry electrografting protocol, to obtain a continuous and uniform film with a growth kinetics compatible with industrial constraints.

Generally speaking, the polarization of the surface to be covered by the film may be produced in a pulsed mode, each cycle of which is characterized by:

(a) a total period P of between 10 ms and 2 s, or in some instances of around 0.6 s;

(b) a polarization time Tₒₙ of between 0.01 and 1 s, or in some instances around 0.36 s, during which a potential difference or a current may be applied to the surface of the substrate; and

(c) an idle period with zero potential or current of a duration of between 0.01 and 1 s, or in some instances around 0.24 s.

In some instances, the aforementioned barrier layer may itself be produced by a wet deposition method, preferably in a liquid medium of protic nature.

The method of preparing an electrically insulating film which has just been described may be also be useful in the preparation of through-vias (e.g., 3D integrated circuits) for constituting the internal electrically insulating layer designed to be coated with the barrier layer serving to prevent copper migration or diffusion. In some aspects of the present disclosure, the barrier layer may serve to prevent copper migration or diffusion and may include a nickel- or cobalt-based metal film.

In some embodiments, methods of preparing a conformal layer 108 by coating a semiconductor substrate 102 with a protic media including those disclosed in U.S. patent application Ser. No. 12/495,137 filed Jun. 30, 2009, which claims priority to French Patent Application No. 08-54442 filed Jul. 1, 2008, each of which is hereby incorporated herein by reference in its entirety for all purposes.

In another aspect of the present disclosure, a method of preparing a nickel-based material as the conformal layer 108 includes initially activating a surface (e.g., oxidized surface) of a silicon substrate 102 by immersing within a solution, followed by subsequently coating the surface with a metal layer electroless metal deposition technique. In this instance, the solution may be characterized in that it contains:

(A) an activator consisting of one or more palladium complexes selected from the group consisting of:
(1) Palladium complexes having the formula (I)

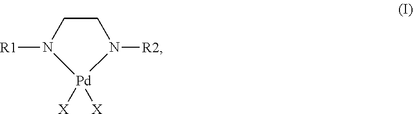

where:
   (a) R1 and R2 are identical and are H, CH₂CH₂NH₂, CH₂CH₂OH; or R1 is H and R2 is CH₂CH₂NH₂; or R1 is CH₂CH₂NH₂ and R2 is CH₂CH₂NHCH₂CH₂NH₂; or R1 is H and R2 is CH₂CH₂NHCH₂CH₂NHCH₂CH₂NH₂; and
   (b) X is a ligand selected from the group consisting of Cl⁻, Br⁻, I—, H₂O, NO₃—, CH₃SO₃, CF₃SO₃⁻, CH₃—Ph—SO₃⁻, and CH₃COO⁻;
(II) Palladium complexes having the formula (IIa) or (IIb)

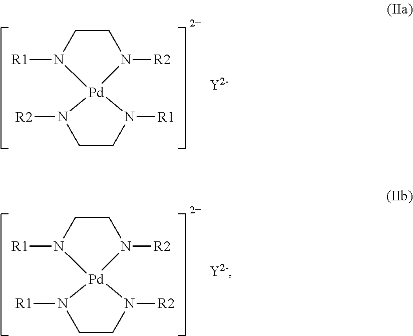

where:
   (a) R1 and R2 are as defined above; and
   (b) Y is a counter-ion comprising two negative charges consisting of:
      (i) Either two monoanions selected from the group consisting of Cl⁻, PF6-, BF⁴⁻, NO₃⁻, CH₃SO₃⁻, CF₃SO₃⁻, CH₃C₆H₄SO₃⁻, and CH₃COO⁻;
      (ii) Or a dianion, preferably SO₄²,

(B) A bifunctional organic binder consisting of one or more organosilane compounds having the general formula:

{NH₂-(L)}₃₋ₙ-Si(OR)ₙ (V), where:
(1) L is a spacing arm selected from the group consisting of CH₂, CH₂CH₂, CH₂CH₂CH₂— and CH₂CH₂NHCH₂CH₂;
(2) R is a group selected from the group consisting of CH₃, CH₃CH₂, CH₃CH₂CH₂, (CH₃)₂CH; and
(3) n is an integer equal to 1, 2 or 3.

(C) A solvent system consisting of one or more solvents suitable for solubilizing the activator and the organosilane solvent.

In accordance with another embodiment with the present invention, a bifunctional organic binder consisting of one or more organosilane compounds can have the general formula:

{X-(L)}₃₋ₙ-Si(OR)ₙ (Va)

where:
X is a functional group selected from the group consisting of thiol, pyridyl, epoxy (oxacyclopropanyl), glycidyl, primary amine, chloro and capable to react with palladium compounds of formula I:
L is a spacing arm selected from the group consisting of CH₂; CH₂CH₂; CH₂CH₂CH₂—; CH₂CH₂CH₂CH₂—; CH₂CH₂NHCH₂CH₂, CH₂CH₂CH₂NHCH₂CH₂, CH₂CH₂CH₂NHCH₂CH₂NHCH₂CH₂, CH₂CH₂CH₂NHCH₂CH₂CH₂CH₂CH₂CH₂, Ph; Ph—CH₂; et CH₂CH₂—Ph—CH₂; (Ph being a phenyl)
R is a group selected from the group consisting of CH₃, CH₃CH₂, CH₃CH₂CH₂, (CH₃)₂CH; et
n is an integer equal to 1, 2 or 3;

or the general formula:

(OR)₃Si-(L)-Si(OR)₃ (Vb)

where:
L is a spacing arm selected from the group consisting of CH₂CH₂CH₂NHCH₂CH₂NHCH₂CH₂CH₂ et CH₂CH₂CH₂—S—S—CH₂CH₂CH₂
R is a group selected from the group consisting of CH₃, CH₃CH₂, CH₃CH₂CH₂, (CH₃)₂CH.

In the following description, compounds having the formula (IIa) and (IIb) may be designated collectively by the name “compounds having the formula (II)”.

According to another feature of the present disclosure, this solution may be free of water or comprises water in a concentration lower than 0.5%, or lower than 0.2%, or lower than 0.1% by volume. This limited quantity of water, combined with the complexed form of the activator, may prevent any inactivation of the solution over time and therefore allows its use on an industrial scale.

According to another particular feature of the disclosure, this solution comprises:
(A) the aforementioned activator in a concentration of 10⁻⁶ M to 10⁻² M, or from 10⁻⁵ M to 10⁻³ M, or from 5×10⁻⁵ M to 5×10⁻⁴ M;
(B) the aforementioned binder in a concentration of 10⁻⁵ M to 10⁻¹ M, or from 10⁻⁴ M to 10⁻² M, or from 5×10⁻⁴ M to 5×10⁻³ M.

In one embodiment, the activator of the solution according to the disclosure consists of one or more palladium complexes having the formulas (I) and (II) defined above.

Complexes having formula (I) can be prepared by reacting a palladium salt having formula (III) with a nitrogenated bidentate ligand having the formula (IV) by the following reaction scheme:

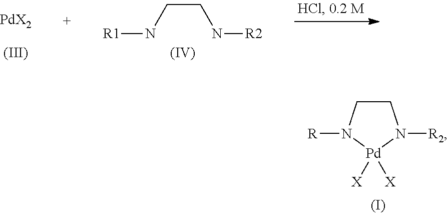

where X, R1 and R2 are similar to those discussed above.

In another embodiment, a palladium salt having the formula (III) is dissolved in an aqueous 0.2 M hydrochloric acid solution at a temperature between 40° C. and 80° C., or about 60° C., for a period of about 10 minutes to about 20 minutes, or about 20 minutes, to obtain the soluble complex having the formula H₂PdCl₄.

At the end of the reaction, an equivalent of a nitrogenated bidentate ligand having the formula (IV) may be added to the reaction medium which may be maintained at a temperature between 40 and 80° C., or about 60° C., for a period of about 1 hour to about 3 hours, or about 2 hours, to yield the complex having the formula (I). The addition of the ligand may cause a change in color of the reaction medium.

The solvent may subsequently be evaporated and the solid residue may be treated by recrystallization in a solvent such as ethanol for example.

Preferably, the starting palladium compound may be palladium chloride PdCl₂.

Alternatively, the palladium salt having formula (III) may be replaced by a palladium salt having the formula [PdX₄]²⁻, such as K₂PdCl₄, Li₂PdCl₄, Na₂PdCl₄ or (NH₄)₂PdCl₄.

Examples of amine derivatives having the formula (IV) suitable for use in the context of the present disclosure include the following compounds:
(1) Diethylenetriamine (compound having formula (IV) where R1 is a hydrogen atom and R2 is a CH₂CH₂NH₂ group); and
(2) N,N′-Bis(2-hydroxyethyl)ethylenediamine (compound having formula (IV) where R1 and R2 are identical and are CH₂CH₂OH).

In one embodiment, the amine compound is diethylenetriamine.

Complexes having the formula (II) can be prepared similarly to the preparation of complexes having formula (I) by the following reaction scheme:

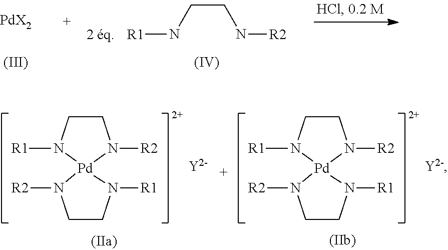

where X, R1 and R2 are similar to those discussed above.

More precisely, a soluble complex is formed having the formula H₂PdCl₄ in a manner identical to that described above.

At the end of the reaction, two equivalents of the nitrogenated bidentate ligand having formula (IV) are added to the reaction medium which is maintained at a temperature between 60° C. and 80° C. or a period of 8 hours to 15 hours, or about 12 hours, to yield the complexes having a formula (IIa) and (IIb).

Alternatively, the complexes having formula (II) can be prepared from complexes having formula (I) by adding an equivalent of the nitrogenated bidentate ligand in an appropriate solvent and by maintaining the reaction medium at a temperature between 60 and 80° C., or about 70° C., for a period of 8 hours to 15 hours, or about 12 hours. In these two cases, the reaction can be facilitated by adding a silver salt to the reaction medium.

The reaction scheme given above shows that the reaction leads to two cis and trans complexes, which are the only complexes formed in the case in which R1 is H and R2 is CH₂CH₂NH₂. Statistical mixtures of several complexes can be obtained in the case in which R1 and R2 are both free radicals having a molecular weight equal to or higher than that of the CH₂CH₂NH₂ group. It has been shown that such mixtures are usable on the industrial scale and need not necessarily be purified to yield the desired result.

The bifunctional organic binder, which constitutes one of the essential components of the solution, consists of one or more compounds having formula (V) defined above. These compounds comprise at least one functional group of the alkoxysilane type suitable for forming a chemical bond with the oxidized surface of the substrate and at least one amine functional group suitable for forming a chemical bond with the palladium complex having formula (I) or (II) defined above.

These compounds provide good adhesion between the successive layers of a substrate having a surface formed of an oxide, in particular when this surface is subsequently covered with a metal layer, in particular of NiB forming a copper diffusion barrier, which is itself covered with a copper seed layer.

Compounds of formula (Va) or (Vb) are, for example, can be selected from the following compounds:
(3-Aminopropyl)triethoxysilane;
(3-Aminopropyl)trimethoxysilane;
m-Aminophenyltrimethoxysilane;
p-Aminophenyltrimethoxysilane;
p,m-Aminophenyltrimethoxysilane;
4-Aminobutyltriethoxysilane;
m,p(Aminoethylaminomethyl)phenethyltrimethoxysilane;
N-(2-Aminoethyl)-3-aminopropyltriethoxysilane;
N-(2-Aminoethyl)-3-aminopropyltrimethoxysilane;
2-(4-Pyridylethyl)triethoxysilane;
Bis(3-trimethoxysilylpropyl)ethylenediamine;
(3-Trimethoxysilylpropyl)diethylenetriamine;
N-(3-Trimethoxysilylethyl)ethylenediamine;
N-(6-Aminohexyl)aminopropyltrimethoxysilane;
(3-Glycidoxypropyl)trimethoxysilane;
(3-Glycidoxypropyl)triethoxysilane;
5,6-Epoxyhexyltriethoxysilane;
(3-Mercaptopropyl)trimethoxysilane;
(3-Mercaptopropyl)triethoxysilane;
Bis[3-(triethoxysilyl)propyl]disulfure;
3-Chloropropyltrimethoxysilane;
3-Chloropropyltriethoxysilane;
(p-Chloromethyl)phenyltrimethoxysilane;
m,p ((Chloromethyl)phenylethyl)trimethoxysilane.

In accordance with one embodiment, organosilane compounds suitable for use in the context of the present invention can be made of:
Compounds having formula (Va) where:

X is NH₂ and

L is CH₂CH₂CH₂— and R is CH₃ (compound named (3-aminopropyl)-trimethoxy-silane or APTMS);

or L is CH₂CH₂CH₂— and R is CH₃CH₂ (compound named (3-aminopropyl)-triethoxy-silane or APTES);

or L is CH₂CH₂NHCH₂CH₂ and R is CH₃ (compound named [3-(2-aminoethyl)aminopropyl]trimethoxy-silane or DATMS or DAMO);

X is SH; L is CH₂CH₂CH₂— and R is CH₂—CH₃ (compound named (3-Mercaptopropyl)trimethoxysilane or MPTES);

or X is C₆H₅N; L is CH₂CH₂— and R is CH₂—CH₃ (compound named 2-(4-Pyridylethyl)triethoxysilane or PETES);

or X is CHCH₂O; L is CH₂CH₂CH₂ and R is CH₃ (compound named (3-Glycidoxypropyl)trimethoxysilane or EPTMS).

or X is Cl; L is CH₂CH₂CH₂ and R is CH₃ (compound named 3-Chloropropyltrimethoxysilane or CPTMS).

An organosilane compound in the context of the present disclosure is 3-aminopropyl-trimethoxy-silane (APTMS).

A bifunctional organic binder is present in the activated solution in a quantity generally between 10⁻⁵ M and 10⁻¹ M, or between 10⁻⁴ M and 10⁻² M, or between 5×10⁻⁴ M and 5×10⁻³ M.

According to a particular feature of the disclosure, the activation solution is free of compound comprising at least two glycidile functions or of a compound comprising at least two isocyanate functions.

The solvent system of the solution according to the present disclosure must be suitable for solubilizing the activator and the binder defined above.

The solvent system may consist of one or more solvents selected from the group consisting of N-methylpyrrolidinone (NMP), dimethylsulphoxide (DMSO), alcohols, ethyleneglycol ethers such as for example monoethyl-diethyleneglycol, propyleneglycol ethers, dioxane and toluene.

In general, the solvent system advantageously consists of a mixture of a solvent suitable for solubilizing the palladium complex in combination with a solvent such as an ethyleneglycol ether or a propyleneglycol ether.

A particularly preferred solvent solution in the context of the present disclosure, due to its very low toxicity, consists of a mixture of N methylpyrrolidinone (NMP) and monoethyl ether of diethyleneglycol. These compounds can be used in a volume ratio between 1:200 and 1:5, or about 1:10.

An activation solution in the context of the present disclosure contains:
(A) An activator consisting of one or more palladium complexes selected from the group consisting of:
   (1) Complexes having the formula (I), where:
      (a) R1 is H, R2 is CH₂CH₂NH₂ and X is Cl, a complex named (diethylenetriamine)(dichloro) palladate (II);
      (b) R1 and R2 are identical and are CH₂CH₂OH and X is Cl, a complex named (N,N′-bis(2-hydroxyethyl)ethylenediamine)-(dichloro) palladate (II);
(2) Complexes having the formula (IIa) where:
   (a) R1 is H, R2 is CH₂CH₂NH₂ and Y is two Cl, a complex named trans-bis(diethylenetriamine) palladate (II);
(3) Complexes having the formula (IIb) where:
   (a) R1 is H, R2 is CH₂CH₂NH₂ and Y is two Cl, a complex named cis-bis(diethylenetriamine) palladate (II);
      in a concentration of 5×10⁻⁵ M to 5×10⁻⁴ M.

(B) A binder consisting of one or more organosilane compounds selected from the group consisting of compounds having formula (Va) where:

X is NH₂ and

L is CH₂CH₂CH₂— and R is CH₃ (APTMS);

or L is CH₂CH₂CH₂— and R is CH₃CH₂(APTES);

or L is CH₂CH₂NHCH₂CH₂ and R is CH₃ (DATMS or DAMO);

X is SH; L is CH₂CH₂CH₂— and R is CH₂CH₃ (MPTES);

or X is CH₅N; L is CH₂CH₂— and R is CH₂CH₃ (PETES);

or X is CHCH₂O; L is CH₂CH₂CH₂ and R is CH₃ (EPTMS);
or X is Cl; L is CH₂CH₂CH₂ and R is CH₃ (CPTMS);
L is CH₂CH₂CH₂— and R is CH₃, a compound named (3 aminopropyl)-trimethoxy-silane or APTMS;
L is CH₂CH₂CH₂⁻ and R is CH₃, a compound named (3 aminopropyl)-triethoxy-silane or APTES;
L is CH₂CH₂NHCH₂CH₂ and R is CH₃, a compound named [3-(2-aminoethyl)aminopropyl]trimethoxy-silane or DATMS or DAMO;
in a concentration between 10⁻³ M and 10⁻² M.

In some embodiments, the conformal layer 108 can be prepared by chemically functionalizing of a substrate 102 with a solution in preparation for subsequent coating by a metal layer deposition technique including those disclosed in French Patent Application No. 09-56800 filed Sep. 30, 2009, which is hereby incorporated herein by reference in its entirety for all purposes.

In some embodiments, the substrate coated with a silicon layer (e.g. silicon dioxide layer) can be activated as described above for electroless deposition of a nickel-based or cobalt-based conformal layer. Nickel or Cobalt can be alloyed with element such as phosphorous or boron or mixture of theses compounds. In some embodiments, the coating of the activated surface may be carried out by contacting the activated surface with a solution comprising:
a. at least one metallic salt preferably between 10⁻³ M and 1 M;
b. at least one reducing agent, preferably between 10⁻⁴ M and 1 M;
c. optionally, at least one stabilizer, preferably between 10⁻³ M and 1 M; and
d. an agent for adjusting the pH to a value between 6 and 11, preferably between 8 and 10;
   under conditions for forming a conformal layer having the desirable thickness as discussed herein.

The metallic salt may be a water soluble alt selected from the group consisting of acetate, acetylacetonate, hexafluoro-phosphate, nitrate, perchlorate, sulphate or tetrafluoroborate of the metal.

The reducing agent can be selected from the group consisting of hydrophosphorous acid and slats thereof, boron derivatives, glucose, formaldehyde and hydrazine. Preferably, the reducing agent is a derivative of borane, for example, dimethylamino borane (DMAB).

The stabilizer can be selected from the group consisting of ethylene diamine, citric acid, acetic acid, succinic acid, malonic acid, aminoacetic acid, malic acid or an alkali metal salt of these compounds.

FIG. 2C shows a pattern 114 being deposited over the conformal layer 108. In one embodiment, the pattern 114 may be screen printed onto the solar cell 100 using chemical etchable photoresist onto to define a pattern 114 for the conformal layer 108. In some embodiments, other suitable photolithographic printing techniques may be incorporated for forming the pattern 114. In other instances, the pattern 114 may be formed by electron-beam or other suitable lithographic printing processes known in the art.

FIG. 2D shows etching of the conformal layer 108 resulting in the desired metal pattern and removal of the photoresist pattern 114. The resulting conformal layer 108 is able to provide a patterned grid on which subsequent processing steps may be carried out.

FIG. 2E shows another pattern 114 for the thin-film silicon layer 106 being formed over the conformal layer 108 and the substrate 102, the process for forming the pattern 114 being similar to that discussed above.

FIG. 2F shows a thin-film silicon layer 106 being formed over the solar cell 100 in accordance with the pattern 114 of FIG. 2E. The silicon layer 106 may be deposited on the solar cell 100 using a chemical vapor deposition (CVD) process or a physical vapor deposition process (PVD). In some instances, the thickness of the silicon layer 106 may be about 1 micron. In other instances, the silicon layer 106 may be thicker or thinner than 1 micron.

FIG. 2G shows removal of the pattern 114 by suitable chemical removal processes known in the art. Specifically, the photoresist may be removed by a wet solvent bath. Removal of the pattern 114 defines the layout of the silicon layer 106 over the conformal layer 108 and the substrate 102.

Although the processes discussed above shows a patterning step followed by deposition of the thin-film silicon layer, it will be appreciated by one skilled in the art that the processes can incorporate a deposition step of the silicon layer followed by pattern/etching of the same. In other words, the thin-film silicon layer 106 may be formed by a damascene process.

FIG. 2H shows another pattern 114 being formed over the solar cell 100. The process for forming the pattern 114, in one embodiment, can be substantially similar to that discussed above.

FIG. 2I shows a conductive layer 110 being formed over the solar cell 100. In one instance, formation of the conductive layer 110 may be substantially similar to that of the conformal layer 108. The conductive layer 110 may be gold, copper, aluminum or alloys thereof, among others. In some embodiments, the conductive layer 110 may be other suitable types of material having enhanced electrical conductivity. In one example, the conductive layer 110 may be formed by electroplating (e.g., light-induced plating) to a thickness of about 10 microns. In other examples, the conductive layer 110 may be formed by light-assisted electroplating or electroless plating, among other deposition methods to a thickness of greater than 10 microns or less than 10 microns depending on the type of application.

FIG. 2J shows removal of the pattern 114 to produce a patterned metal contact 110. In one example, the pattern 114 is a chemical etch photoresist that may be removed by a wet chemical solvent bath. In other instances, the pattern 114 may be removed by suitable dry etch and/or wet etch chemistries, among other techniques. After the pattern 114 has been removed, the remaining metal contact 110 maintains the layout of the pattern 114, and solar cell 100, such as that shown in FIG. 1, is provided.

Although a process is illustrated in FIGS. 2A-2J as one embodiment of the present invention, it should be appreciated that the steps illustrated there in can be modified, varied, or combined, or otherwise substituted with methods known in the art, so long as the solar cell 100, as shown, in FIG. 1 can be obtained.

### Applications

The solar cell 100 made in accordance with an embodiment of the present disclosure includes a substrate, a conformal layer deposited over the surface of the substrate, and interconnects formed over the conformal layer. The conformal layer of the present invention, as noted above, can act to facilitate the conversion of light energy into electrical current while minimizing energy loss, such that the overall conversion efficiency of the solar cell 100 can be improved when compared to other commercially available solar cells. In particular, the material from which the conformal layer is made has relatively low resistivity to electrical current so as to minimize disruption while improving overall transmission of the electrical current along the solar cell 100, such that more of the electrical current can be available for use.

In some aspects of the invention, the solar cell 100 manufactured in accordance with an embodiment of the present invention can also be provided with improved ohmic contact to the interconnect and can be manufactured at relatively lower cost when compared to those commercially available photovoltaic devices, such as those having a TCO layer.

The solar cell 100, made in accordance with an embodiment of the present disclosure, further allows individual cells to be wider (for example twice as large) as current designs, meaning half as many cells per solar panel. Accordingly, an increase in active area can be added to the solar panel. This may result in lower voltage output per cell due to fewer cells per panel in series, such that more panels can be connected to a single inverter.

In some embodiments, a plurality of solar cells 100 may be interconnected in series or in parallel to produce solar panels and/or solar modules, the modules having conversion efficiency similar to those of individual solar cells. Additional resistors, capacitors, converters, among other electrical and/or mechanical devices, may be incorporated as known by one skilled in the art. In other embodiments, the solar cells may be coupled to form photovoltaic arrays. In yet other embodiments, the solar cells may be used in multi-touch screens, flat panel displays, touch screens, to name a few. The solar cells may be used in powering devices such as multi-touch screens, flat panel displays, touch screens, etc. The flat panel displays and touch screens may be used in consumer products, mobile devices and medical devices, among others. In other instances, the solar modules and/or photovoltaic arrays may be used for supplying electrical power to signages, street lights, and other lighting devices with or without the use of additional external power supplies (e.g., batteries). In some embodiments, the solar module and/or solar array may serve as a bridge or to supplement consumer electronics products and traditional power source, such as a battery and electrical cable outlet.

While the invention has been described in connection with the specific embodiments thereof, it will be understood that it is capable of further modification. Furthermore, this application is intended to cover any variations, uses, or adaptations of the invention, including such departures from the present disclosure as come within known or customary practice in the art to which the invention pertains.

What is claimed is:

1. A solar cell comprising:
a substrate for permitting external radiation to pass therethrough;
a functional layer formed over the substrate to facilitate conversion of the external radiation into electrical current and to provide an electrical connection along the solar cell; and
a substantially transparent conformal layer deposited between the substrate and the functional layer, and made from a material having low resistivity to electrical current so as to minimize disruption while improving overall transmission of the electrical current from the functional layer along the conformal layer, such that more of the electrical current can be available for use.

2. The solar cell of claim 1, wherein the substrate is made from one of glass, quartz, sapphire, or a material transparent to external radiation.

3. The solar cell of claim 1, wherein the functional layer includes a semiconductor layer for use in facilitating conversion of external radiation into electrical current.

4. The solar cell of claim 3, wherein the semiconductor layer includes a light-absorbing silicon material.

5. The solar cell of claim 1, wherein the functional layer includes a metal layer for use as an electrode for the solar cell.

6. The solar cell of claim 5, wherein the metal layer can be configured to define a patterned circuit.

7. The solar cell of claim 1, wherein the conformal layer is made from a substantially thin metal-based material.

8. The solar cell of claim 7, wherein the metal-based material includes one of a nickel-based material, a cobalt-based material, a titanium-based material, tantalum-based material, nitride-based material, silicon-nitride based material, titanium-nitride based material, tantalum-nitride based material, titanium-tantalum based material, their alloys, or a combination thereof.

9. The solar cell of claim 7, wherein the metal-based material includes nickel-boron.

10. The solar cell of claim 1, wherein the material from which the conformal layer is made can lessen contact resistance to the interconnect.

11. The solar cell of claim 1, wherein the conformal layer has a thickness of less than about 100 nm.

12. The solar cell of claim 1, wherein the conformal layer provides a pathway along which electrical current can be transmitted through the solar cell.

13. A method for manufacturing a solar cell, the method comprising:
providing a substrate that can permit external radiation to pass therethrough;
depositing, on the substrate, a substantially thin conformal layer made from a material having relatively low resistivity to electrical current and that can minimize disruption while improving overall transmission of electrical current along the solar cell; and
placing, on the conformal layer, a functional layer designed to facilitate conversion of external radiation into electrical energy and to provide an electrical connection to the conformal layer for transmission of electrical current along the solar cell.

14. The method of claim 13, wherein, in the step of providing, the substrate is made from one of glass, quartz, sapphire, or a material transparent to external radiation.

15. The method of claim 13, wherein, in the step of depositing, the conformal layer is made from a metal-based material.

16. The method of claim 15, wherein, in the step of depositing, the metal-based material includes one of a nickel-based material, a cobalt-based material, a titanium-based material, tantalum-based material, nitride-based material, silicon-nitride based material, titanium-nitride based material, tantalum-nitride based material, titanium-tantalum based material, their alloys, or a combination thereof.

17. The method of claim 15, wherein, in the step of depositing, the metal-based material includes nickel-boron.

18. The method of claim 13, wherein the step of depositing includes defining a pattern for the conformal layer.

19. The method of claim 13, wherein the step of placing includes providing a semiconductor layer for use in facilitating conversion of external radiation into electrical current.

20. The method of claim 19, wherein, in the step of providing, the semiconductor layer includes a light-absorbing silicon material.

21. The method of claim 19, wherein the step of providing includes defining a pattern for the semiconductor layer.

22. The method of claim 13, wherein the step of depositing includes providing a metal layer for use as an electrode for the solar cell.

23. The method of claim 22, wherein the step of providing includes configuring the metal layer to define a patterned circuit.

24. A method for converting light radiation to electrical energy, the method comprising:
providing a functional layer that can act to facilitate conversion of light radiation into electrical current and to provide an electrical connection for the transmission of the electrical current;
positioning, against a surface of the functional layer, a substantially thin conformal layer made from a material having relatively low resistivity to electrical current and that can minimize disruption while improving overall transmission of electrical current from the functional layer along the conformal layer;
directing light radiation through the conformal layer to the functional layer; and
converting the light radiation reaching the functional layer into electrical current for subsequent use.

25. The method of claim 24, wherein the step of providing includes further providing a semiconductor layer.

26. The method of claim 24, wherein the step of providing includes further providing a metal layer, on a surface of the semiconductor opposite the surface against which the conformal layer is positioned, for use as an electrode.

27. The method of claim 24, wherein, in the step of placing, the conformal layer is made from a metal-based material.

28. The method of claim 27, wherein, in the step of placing, the metal-based material includes one of a nickel-based material, a cobalt-based material, a titanium-based material, tantalum-based material, nitride-based material, silicon-nitride based material, titanium-nitride based material, tantalum-nitride based material, titanium-tantalum based material, their alloys, or a combination thereof.

29. The method of claim 27, wherein, in the step of placing, the metal-based material includes nickel-boron.

30. The method of claim 24 further including positioning the conformal layer onto a substrate made from a transparent material to permit light radiation to pass therethrough.

31. The method of claim 24 further including allowing electrical current converted from light radiation to flow from the functional layer into and along the conformal layer.

32. The method of claim 24 further including allowing the conformal layer to transmit electrical energy therealong while minimizing energy loss, such that more of the electrical current can be available for use.

33. The solar cell of claim 1 for use in connection with one of consumer products, mobile devices, medical devices, electronic devices, among others.

34. The solar cell of claim 1 for use in powering devices.

35. The solar cell of claim 1 for use in powering multi-touch screens, flat panel displays, and touch screens.

36. The solar cell of claim 1 for use in powering signages, street lights, and other lighting devices.
